(19) United States
(12) Patent Application Publication
(10) Pub. No.: US 2026/0093302 A1
(43) Pub. Date: Apr. 2, 2026

(54) INTRINSIC TEMPERATURE MEASUREMENT FOR CROSS TEMPERATURE HANDLING IN MEMORY DEVICES

(71) Applicant: MICRON TECHNOLOGY, INC., Boise, ID (US)

(72) Inventors: Li-Te Chang, San Jose, CA (US); Chao-Han Cheng, San Jose, CA (US); Murong Lang, San Jose, CA (US)

(21) Appl. No.: 19/335,679

(22) Filed: Sep. 22, 2025

Related U.S. Application Data
(60) Provisional application No. 63/701,774, filed on Oct. 1, 2024.

(51) Int. Cl. G06F 1/20; G06F 12/10

(52) U.S. Cl. CPC G06F 1/206; G06F 12/10

(57) ABSTRACT

A system includes a memory device and a processing device, operatively coupled with the memory device, to perform operations including measuring a read temperature metric associated with a segment of the memory device; estimating a read temperature based on the read temperature metric; determining a cross temperature value based on the read temperature and a write temperature; determining a set of cross temperature voltage offsets associated with the cross temperature value; and associating the set of cross temperature voltage offsets with the segment of the memory device.

### RELATED APPLICATIONS

This application claims the benefit of U.S. Provisional Patent Application No. 63/701,774, filed Oct. 1, 2024, the entire contents of which are incorporated by reference herein.

### TECHNICAL FIELD

Embodiments of the disclosure relate generally to memory sub-systems, and more specifically, relate to using intrinsic temperature measurement for cross temperature handling in memory devices.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2 is a flow diagram of an example method to use intrinsic temperature measurement to implement a cross temperature offset bin in addition to a threshold voltage offset bin to adjust read level voltage offsets, in accordance with some embodiments of the present disclosure.

FIG. 3 schematically illustrates the temporal voltage shift caused by the slow charge loss exhibited by triple-level memory cells, in accordance with some embodiments of the present disclosure.

FIG. 4 schematically illustrates a set of predefined threshold voltage offset bins, in accordance with embodiments of the present disclosure.

FIG. 5 schematically illustrates examples of data state metric used with threshold voltage offset bins and cross temperature metric used with cross temperature offset bins, in accordance with embodiments of the present disclosure.

FIGS. 6A and 6B are examples of a set of threshold voltage offset bins in accordance with some embodiments of the present disclosure.

FIG. 7 is a flow diagram of an example method to use intrinsic temperature measurement to implement a cross temperature offset bin, in accordance with some embodiments of the present disclosure.

FIG. 8 schematically illustrates a relation between the read temperature and the measured read temperature metric, in accordance with some embodiments of the present disclosure.

FIGS. 9A and 9B are examples of a set of cross temperature offset bins in accordance with some embodiments of the present disclosure.

FIG. 10 is a block diagram of an example computer system in which embodiments of the present disclosure may operate.

### DETAILED DESCRIPTION

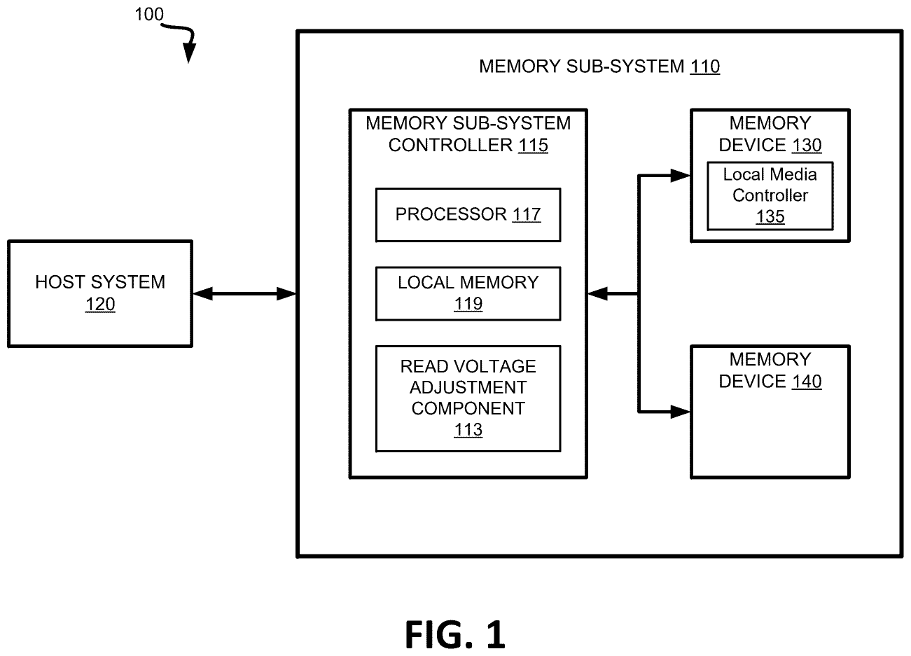

Aspects of the present disclosure are directed to use an intrinsic measurement representing temperature to implement a cross temperature offset bin in addition to a threshold voltage offset bin to adjust read level voltage offsets. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can utilize one or more memory devices, including any combination of the different types of non-volatile memory devices and/or volatile memory devices, to store the data provided by the host system. One example of a non-volatile memory device is a negative-and (NAND) memory device. Other examples of non-volatile memory devices are described below in conjunction with FIG. 1. A non-volatile memory device is a package of one or more dies. Each die includes one or more planes. For some types of non-volatile memory devices (e.g., NAND devices), each plane includes a set of physical blocks. Each block consists of a set of pages. “Block” herein shall refer to a set of contiguous or non-contiguous memory pages. An example of “block” is “erasable block,” which is the minimal erasable unit of memory, while “page” is a minimal writable unit of memory. Each page includes a set of memory cells. A memory cell is an electronic circuit that stores information. “Block family” herein shall refer to a possibly noncontiguous set of memory cells (which can reside in one or more full and/or partial blocks, the latter referred to as “partitions” herein) that have been programmed within a specified time window and a specified temperature window, and thus are expected to exhibit similar or correlated changes in their respective data state metrics in terms of temporal voltage shift. A block family may be formed with any granularity, containing only whole codewords, whole pages, whole super pages, or whole superblocks, or any combination of these.

A memory device includes multiple memory cells capable of storing, depending on the memory cell type, one or more bits of information. One type of cell is a single level cell (SLC), which stores 1 bit per cell and defines 2 logical states (“states”) (“1” or “L0” and “0” or “L1”) each corresponding to a respective V_{T} level. Another type of cell is a multi-level cell (MLC), which stores 2 bits per cell and defines 4 states (“11” or “L0”, “10” or “L1”, “01” or “L2” and “00” or “L3”) each corresponding to a respective V_{T} level. Another type of cell is a triple level cell (TLC), which stores 3 bits per cell and defines 8 states (“111” or “L0”, “110” or “L1”, “101” or “L2”, “100” or “L3”, “011” or “L4”, “010” or “L5”, “001” or “L6”, and “000” or “L7”) each corresponding to a respective V_{T} level. Another type of a cell is a quad-level cell (QLC), which stores 4 bits per cell and defines 16 states L0-L15, where L0 corresponds to “1111” and L15 corresponds to “0000”. Another type of cell is a penta-level cell (PLC), which stores 5 bits per cell and defines 32 states. Other types of cells are also contemplated. Thus, an n-level cell can use 2ⁿ levels of charge to store n bits. A memory device can include one or more arrays of memory cells such as SLCs, MLCs, TLCs, QLCs, PLCs, etc. or any combination of such. For example, a memory device can include an SLC portion, and an MLC portion, a TLC portion, a QLC portion, or a PLC portion of cells.

Various data operations (e.g., write, read, erase, etc.) can be performed by the memory sub-system. A memory cell can be programmed (written to) by applying a certain voltage to the cell, which results in an electric charge being held by the cell. For example, a voltage signal V_{CG} that can be applied to a control electrode of the cell to open the cell to the flow of electric current across the cell, between a source electrode and a drain electrode. More specifically, for each individual cell (having a charge Q stored thereon) there can be a threshold control gate voltage V_{T} (also referred to as the “threshold voltage”) such that the source-drain electric current is low for the control gate voltage (V_{CG}) being below the threshold voltage, V_{CG}<V_{T}. The current increases substantially once the control gate voltage has exceeded the threshold voltage, V_{CG}>V_{T}. Because the actual geometry of the electrodes and gates varies from cell to cell, the threshold voltages can be different even for cells implemented on the same die. The cells can, therefore, be characterized by a distribution P of the threshold voltages, P(Q, V_{T})=dW/dV_{T}, where dW represents the probability that any given cell has its threshold voltage within the interval [V_{T}, V_{T}+dV_{T}] when charge Q is placed on the cell. Valleys can be located between pairs of adjacent programming distributions. A valley can refer to an area or a region between a pair of adjacent programming distributions. The relative width of a valley can be approximated by valley margin. Valley margin can refer to a relative width or relative margin between pairs of adjacent programming distributions. Valley margin can refer to an absolute measurement in volts (e.g., millivolts (mV)) between two adjacent programming distributions.

A memory device can exhibit threshold voltage distributions P(Q,V_{T}) that are narrow compared with the working range of control voltages tolerated by the cells of the device. Accordingly, multiple non-overlapping distributions P(Qₖ, V_{T}) (“valleys”) can be fit into the working range allowing for storage and reliable detection of multiple values of the charge Qₖ, k=1, 2, 3 . . . . The distributions (valleys) are interspersed with voltage intervals (“valley margins”) where none (or very few) of the cells of the device have their threshold voltages. Such valley margins can, therefore, be used to separate various charge states Qₖ—the logical state of the cell can be determined by detecting, during a read operation, between which two valley margins the respective threshold voltage V_{T} of the cell resides. Specifically, the read operation can be performed by comparing the measured threshold voltage V_{T} exhibited by the memory cell to one or more reference voltage levels corresponding to known valley margins (e.g., centers of the margins) of the memory device (“read level threshold”).

A read level calibration can be performed to keep each read level threshold centered so that the memory component can achieve the best overall bit error rate (BER) possible. A memory cell (or memory component, etc.) that is calibrated has a center value that corresponds to a read level threshold (or read level trim) that is centered in or at a lowest point in the read threshold valley and results in a lowest bit error rate (BER). BER can refer to a ratio of a number of bits in error of a data vector divided by a total number of bits for the given data vector. A trim can refer to digital value that is used for a circuit, such as a register, that is converted into an analog voltage value. For example, the read level threshold trims can be programmed into a read level threshold register, which produces a read level threshold voltage used to read data from a memory cell.

Due to the phenomenon known as slow charge loss (SCL), the threshold voltage V_{T} of a memory cell can change with time as the electric charge of the cell is diminishing, the process sometimes referred to as “temporal voltage shift” (TVS). TVS can include different components such as intrinsic charge loss, system charge loss, quick charge loss, etc. TVS generally increases with increasing number of by Program Erase Cycles (PEC), higher temperatures, and higher program voltages. TVS can show significant die-to-die variation. Since typical cells store negatively charged particles (electrons), the loss of electrons causes the threshold voltages to shift along the voltage axis towards lower threshold voltages V_{T}. The threshold voltages can change rapidly at first (immediately after the memory cell is programmed) while slowing down at larger times in an approximately log-linear or power-law fashion (ΔV_{T}(t)=−C*t^{b}) with respect to the time t elapsed since the cell programming event.

In some memory sub-systems, TVS can be mitigated by keeping track of the time elapsed since the programming event as well as of the environmental conditions of a particular memory partition (block, plane, etc.) such as temperature and associating a voltage offset ΔV_{T} per valley to be used during read operations, where the standard “base read level” threshold voltage V_{T} (displayed by the cell immediately after programing) is modified by the voltage offset: V_{T}→V_{T}+ΔV_{T} where ΔV_{T} is negative due to charge loss. Whereas TVS is a continuous process and the compensating for ΔV_{T}(t) can be a continuous function of time, adequate accuracy of offsets can be achieved in some embodiments with a discrete number of threshold voltage offset “bins.” For example, the voltage offset associated with each threshold voltage offset bin, when applied to the base read level, minimizes error rates, i.e., there is no other threshold voltage offset set for a specific bin that results in lower error rates. However, these voltage offsets associated with threshold voltage offset bins are generally determined during manufacturing and typically based on partial dies in the worst-case end of life conditions, in which, for example, the lower levels in the threshold voltage offset bins are static and only the highest level is measured for the characterization. The effect caused by the temperature variation between write and read of the memory cells are not considered in such determination of the voltage offsets associated with threshold voltage offset bins. This is especially the case when the memory devices are used in automotive industry, where the temperature range can vary, e.g., from −40 C to 130 C. In some cases, a mechanism may be implemented to compensate the read level threshold calibration with additional consideration of the threshold voltage shift caused by the temperature variation between write and read of the memory cells. However, to implement such compensation, measuring the temperature at the read operation of the memory cells may require external temperature measuring devices, leading to cost inefficiency and performance degradation. Using a built-in temperature sensor may take certain time to measure the temperature and also require space to store the temperature information. Retrieving the temperature information may also increase the latency, causing system overhead.

Aspects of the present disclosure address the above-referenced and other deficiencies by implementing a memory sub-system that uses a read temperature metric that reflects a temperature of memory device at the time of performing a read operation on the memory cell(s). Specifically, the read temperature metric may be measured as a half valley margin of threshold voltage for the lowest state of the memory cell(s). As described above, a valley margin can refer to an absolute difference (e.g., in millivolts (mV)) between two adjacent programming distributions, and a half valley margin for the lowest state can thus refer to a half value of the absolute difference between the lowest programming distribution and its adjacent programming distribution. The memory sub-system controller may estimate the read temperature based on the measured read temperature metric using a look-up data structure or a preset formula. The look-up data structure or a preset formula may reflect the relationship between the read temperature metric and the read temperature and may be preset, for example, according to testing data.

Upon estimating the read temperature, the memory sub-system controller may retrieve a write temperature, which is obtained during the write operation and stored in the memory sub-system, that represents a temperature at the time of performing the write operation on the memory cell(s). By subtracting the write temperature from the read temperature by, the memory sub-system controller may estimate the temperature difference between temperature at the time of the write operation and the temperature at the time of the read operation (“cross temperature”). The memory sub-system controller can use the cross temperature value to identify a set of voltage offsets (“cross temperature voltage offsets”) which, when applied to the base read level, would minimize error rates caused by the temperature variation between the write operation and the read operation.

The set of cross temperature voltage offsets can be implemented as a cross temperature offset bin (which is similar to the threshold voltage offset bin used to compensate for the SCL). Specifically, each cross temperature offset bin is associated with a set of cross temperature voltage offsets, and each cross temperature offset bin corresponds to a respective cross temperature. The set of cross temperature voltage offsets associated with each cross temperature offset bin may be pre-characterized (e.g., during manufacturing). As such, the memory sub-system controller can use the cross temperature value to identify a set of cross temperature voltage offsets via the cross temperature offset bin, and then the memory sub-system controller can associate the set of cross temperature voltage offsets (i.e., the cross temperature offset bin) with the memory cell(s). When a read operation is performed on the memory cell(s), the memory sub-system controller can apply the set of cross temperature voltage offsets, in addition to the set of threshold voltage offsets described above, to a base read level voltage associated with the memory cells to obtain modified threshold voltage. The memory sub-system controller can read the data from the memory cell(s) using the modified threshold voltage. As such, the memory sub-system controller can compensate for the offsets to the read level threshold voltages associated with the memory cell(s), taking into the consideration the cross-temperature difference between write and read as well as the slow charge loss (SCL).

Advantages of the present disclosure include reducing system error rates and improving overall quality of service (QoS) by intrinsic measurement of the read temperature, thus improving read level threshold voltage calibration. Aspects of the present disclosure reduce the cross-temperature effect and the data retention trigger rates, reduce the error rates, and free up error-recovery related resources to be used for other operations, thus reducing the latency and improving the system performance.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local controller 132) on the die and a controller (e.g., memory sub-system controller 115) for media management within the same memory device package. An example of a managed memory device is a managed NAND (MNAND) device.

The memory sub-system 110 includes a read voltage adjustment component 113 that can use a metric that can be measured internally in the memory device as a read temperature metric, and use the measured read temperature metric to determine a read temperature. Upon determining the read temperature, the memory sub-system controller may retrieve a write temperature and obtain a cross temperature value that reflects the temperature difference between the time of the write operation and the read operation. The memory sub-system controller can use the cross temperature value to determine a set of voltage offsets (“cross temperature voltage offsets”), which, when applied to the base read level, minimizes error rates caused by the temperature variation between write and read of the memory cells. In some embodiments, the memory sub-system controller 115 includes at least a portion of the read voltage adjustment component 113. In some embodiments, the read voltage adjustment component 113 is part of the host system 110, an application, or an operating system. In other embodiments, local media controller 135 includes at least a portion of read voltage adjustment component 113 and is configured to perform the functionality described herein. Further details with regards to the operations of the read voltage adjustment component 113 are described below.

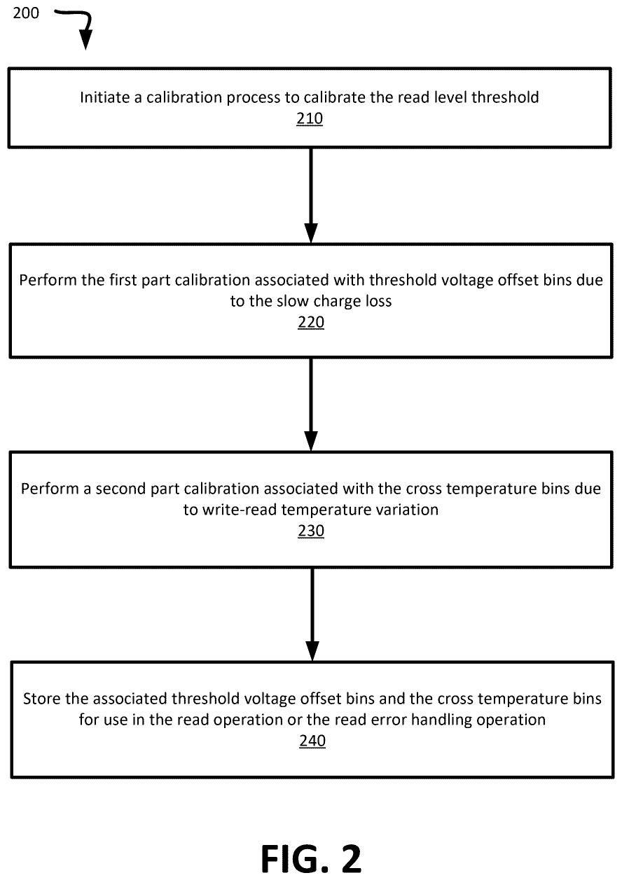

FIG. 2 is a flow diagram of an example method 200 to use intrinsic temperature measurement to implement a cross temperature offset bin in addition to a threshold voltage offset bin to adjust read level voltage offsets, in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the read voltage adjustment component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

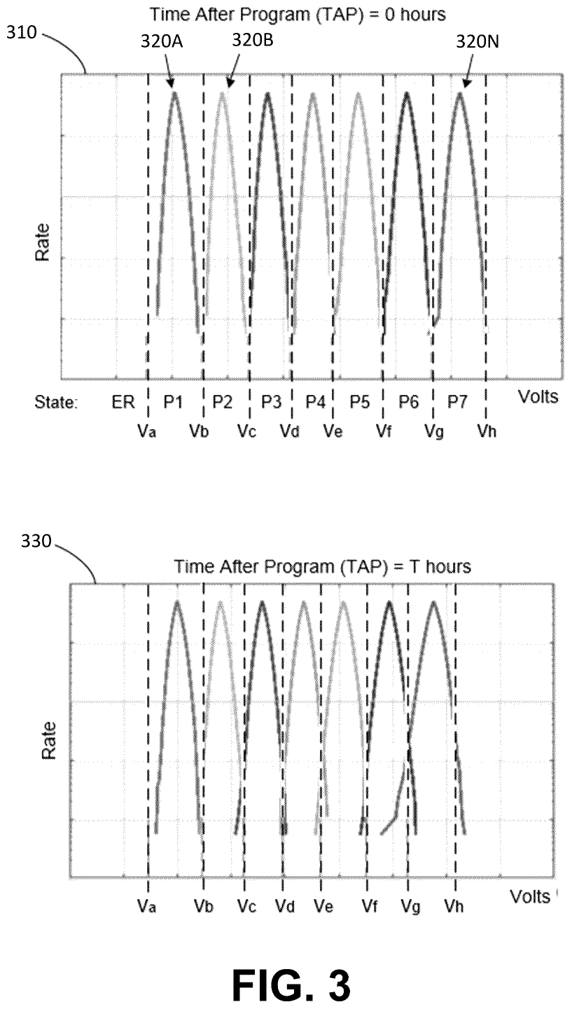

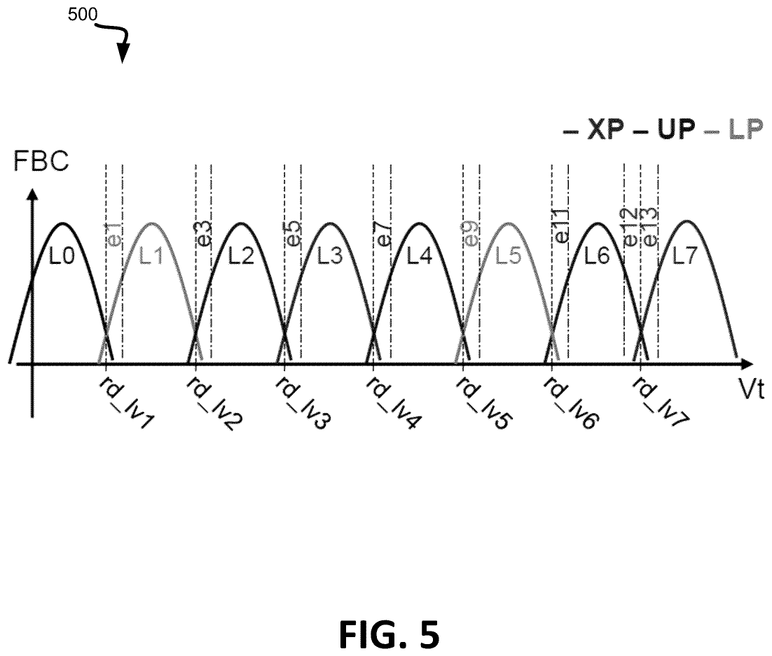

At operation 210, the processing device may initiate a calibration process to calibrate the read level threshold voltage (i.e., the center of a voltage valley for a state of each memory cell). The calibration process may be divided into two parts, the first part of calibration is associated with threshold voltage offset bins to mitigate the slow charge loss (“first part calibration”), and the second part of calibration is associated with the cross temperature offset bins to mitigate the write-read temperature variation (“second part calibration”). The detail of first part calibration associated with threshold voltage offset bins due to the slow charge loss is illustrated in operation 220 along with FIGS. 3, 4, 5, 6A and 6B. The detail of second part calibration associated with the cross temperature offset bins due to write-read temperature variation is illustrated in operation 230 along with FIGS. 5, 7, 8, 9A and 9B.

In some implementations, the processing device may periodically perform the calibration process. Performing the calibration process of a center of a voltage valley may use different measurement methods. Performing the calibration process provides appropriate read level adjustment to prevent significant errors that can occur due to charge change mechanisms such as disturbs, retention, SCL and write-read temperature variation that can alter the data Vₜ voltage distributions stored in the cell.

In some implementations, the calibration process is performed to a block family. Block families can be created asynchronously with respect to block programming events.

Block family creation is the process of opening a block family, maintaining that open block family for a duration, and then closing that block family. Opening a block family starts a time during which the drive may write data to the block family or may read data from the block family. Closing a block family starts a time during which the drive may read data from the block family but not write data to the block family. Invalidating the block family starts a time during which the block family contains no data which has not been rendered invalid, normally through garbage collection.

In an illustrative example, a new block family can be created (“opened”) whenever a specified period of time Δt (e.g., a predetermined number of minutes) has elapsed since creation of the last block family or whenever the reference temperature of memory cells has changed by more than a specified threshold ΔΘ (e.g. 10 C, 20 C, or any other value). Similarly, the family can be “closed” (and a new family can be created) after the time Δt has elapsed since the family was created or if the reference temperature has changed (in either direction) by more than ΔΘ. A memory sub-system controller can maintain an identifier of the active block family, which is associated with one or more blocks as they are being programmed.

At operation 220, the processing device may perform the first part calibration associated with threshold voltage offset bins due to the slow charge loss. FIG. 3 schematically illustrates the temporal voltage shift caused by the slow charge loss exhibited by triple-level memory cells, in accordance with some embodiments of the present disclosure. While the illustrative example of FIG. 3 utilizes triple-level cells, the same observations can be made and, accordingly, the same remedial measures are applicable to single level cells and multi-level cells, as well as any other fractional or whole number of bits per cell (e.g., 3.5 bits per cell, etc.), in order to compensate for the slow charge loss.

Each of charts 310 and 330 illustrate program voltage distributions 320A-320N of memory cells programmed by a respective write level (which can be assumed to be at the midpoint of the program distribution) to encode a corresponding logical level (“000” through “111” in case of a TLC). The program distributions 320A through 320N can illustrate the range of threshold voltages (e.g., normal distribution of threshold voltages) for memory cells programmed at respective write levels (e.g., program voltages). In order to distinguish between adjacent program distributions (corresponding to two different logical levels), the read threshold voltage levels (shown by dashed vertical lines) are defined, such that any measured voltage that falls below a read threshold level is associated with one program distribution of the pair of adjacent program distributions, while any measured voltage that is greater than or equal to the read threshold level is associated with another program distribution of the pair of neighboring distributions.

In chart 310, eight states of the memory cell are shown below corresponding program distributions (except for the state labeled ER, which is an erased state, for which a distribution is not shown). Each state corresponds to a logical level. The read threshold voltage levels are labeled Va-Vh. As shown, any measured voltage below Va is associated with the ER state. The states labeled P1, P2, P3, P4, P5, P6, and P7 correspond to distributions 320A-320N, respectively.

Time After Program (TAP) herein shall refer to the time since a cell has been written and is the primary driver of TVS (temporal voltage shift) along with temperature. TVS captures SCL as well as other charge loss mechanisms. TAP can be estimated (e.g., inferred from a data state metric, such as a shift of threshold voltage or a bit error rate), or directly measured (e.g., from a controller clock). A cell, block, page, block family, etc. is young (or, comparatively, younger) if it has a (relatively) small TAP and is old (or, comparatively, older) if it has a (relatively) large TAP. A time slice is a duration between two TAP points during which a measurement can be made (e.g., perform reference calibration from X to Y minutes or hours after program). A time slice can be referenced by its center point.

As seen from comparing example charts 310 and 330, which reflect the time after programming (TAP) of 0 (immediately after programming) and the TAP of T hours (where T is a number of hours), respectively, the program distributions change over time due primarily to slow charge loss. In order to reduce the read bit error rate, the corresponding read threshold voltages need to be adjusted to compensate for the shift in program distributions, which are shown by dashed vertical lines. In various embodiments of the disclosure, the temporal voltage shift is selectively tracked for die groups based on measurements performed at one or more representative dice of the die group. Based on the measurements made on representative dice of a die group that characterize the temporal voltage shift and operational temperature of the dice of the die group, the threshold voltage offsets used to read the memory cells for the dice of the die group are updated and are applied to the base read threshold levels to perform read operations.

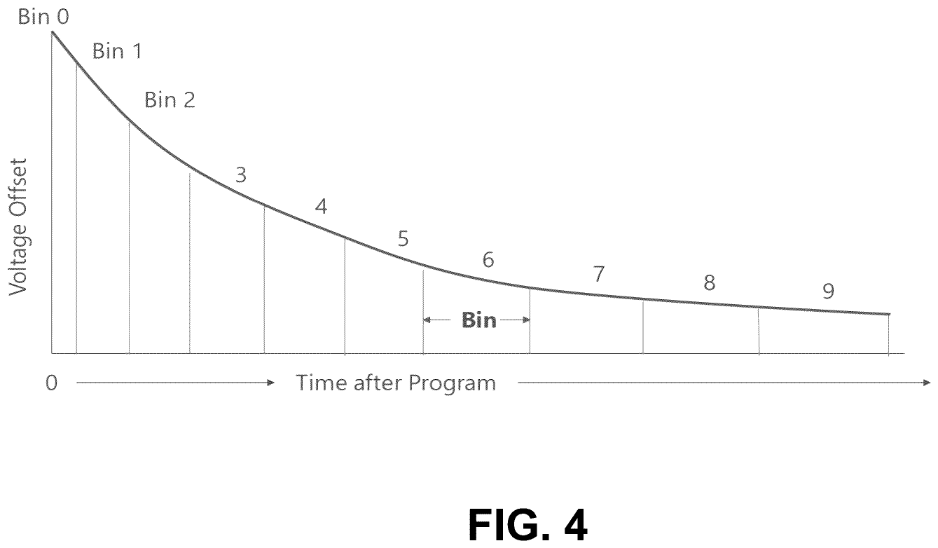

FIG. 4 schematically illustrates a set of threshold voltage offset bins (bin-0 to bin 9), in accordance with embodiments of the present disclosure. As schematically illustrated by FIG. 4, the threshold voltage offset graph can be subdivided into multiple threshold voltage offset bins, such that each bin corresponds to a range of threshold voltage offsets. While the illustrative example of FIG. 4 defines ten bins, in other implementations, various other numbers of bins can be employed (e.g., 64 bins).

In some implementations, the memory sub-system controller can associate a segment of memory device with a threshold voltage offset bin during a periodically performed calibration process. The first part calibration process selects the set of threshold voltage offsets to be applied to the base voltage read level in order to perform read operations. The first part calibration process involves performing, with respect to a specified number of selected pages or blocks that is being calibrated, read operations utilizing different set of threshold voltage offsets, and choosing the set of threshold voltage offset that results in a defined error rate (e.g., a bit error rate) of the read operation. The defined error rate can be a minimum error rate, or it can be an error rate that falls within a certain range. The threshold voltage offset bin may be determined using various techniques, including block family error avoidance (BFEA). That is, a segment of the memory device may be memory cells in any granularity (e.g., cells, pages, blocks, planes, dies, etc.), and memory cells can be grouped using different techniques to be associated with one or more of the threshold voltage offset bins. According to BFEA, families of blocks (or any other memory partitions) programmed within a specified time window and/or under similar environmental (e.g., temperature) conditions can be associated with one of the threshold voltage offset bins. Given that wear-leveling keeps programmed at similar program-erase cycles (PECs), the time elapsed since programming and temperature conditions are among the main factors affecting the amount of TVS, different partitions within a single block family can be presumed to exhibit similar distributions of threshold voltages of their memory cells, and thus would require the same voltage offsets to be applied to the base read levels for read operations.

Referring back to FIG. 2, the processing device may perform a first part calibration in order to associate partitions of various families with one of the threshold voltage offset bins. Each threshold voltage offset bin, in turn, can be associated with a set of voltage offsets to be applied for read operations described with respect to operation 240.

The first part calibration process can evaluate a data state metric (e.g., a shift of threshold voltage or bit error rate) for each die of each block family with one of a set of predefined threshold voltage offset bins, e.g., by, for each die of each block family, measuring a value of data state metric of a block (of the block family) stored on the die. An example of measuring a data state metric is illustrated in FIG. 5. As shown in FIG. 5, the data state metric may be calculated based on one or more values of a half valley margin of threshold voltage for a highest state of a memory cell, for example, the data state metric may equal (e13−e12)/2.

Referring back to FIG. 2, the first part calibration process can then update a bin pointer (“threshold voltage offset bin pointer”) associated with the die and block family to point to a threshold voltage offset bin that corresponds to the measured value of the data state metric. Each threshold voltage offset bin is in turn associated with voltage offsets to be applied for read operations; for TLC with 8 distributions (levels) there are 7 valleys and for a given threshold voltage offset bin, which includes 7 offsets, one for each valley. For example, the bin pointer can remain the same if the data state metric is in a range associated with the existing bin pointer, or can be changed to point to an older bin if the data state metric is in a range associated with the older bin.

Generally, the temporal voltage shift for younger block families (i.e., block families that are more recently created) is more significant than the temporal voltage shift for older block families (i.e., block families that are less recently created). The processing device can periodically perform the calibration process for each block family based on the age of the block family, which corresponds to the threshold voltage offset bin associated with the block family. For example, in an 8 threshold voltage offset bin architecture, newly created block families can be associated with threshold voltage offset bin-0, while the oldest (i.e., least recently created) block families are associated with threshold voltage offset bin 7. The processing device performs the calibration process for the block families in threshold voltage offset bin-0 more frequently than for the block families in threshold voltage offset bin 7, based on the age of the block families associated with threshold voltage offset bin-0 (e.g., based on the logarithmic linear nature of SCL). The associations of blocks with block families and block families and dies with threshold voltage offset bins can be stored in respective metadata tables maintained by the memory sub-system controller.

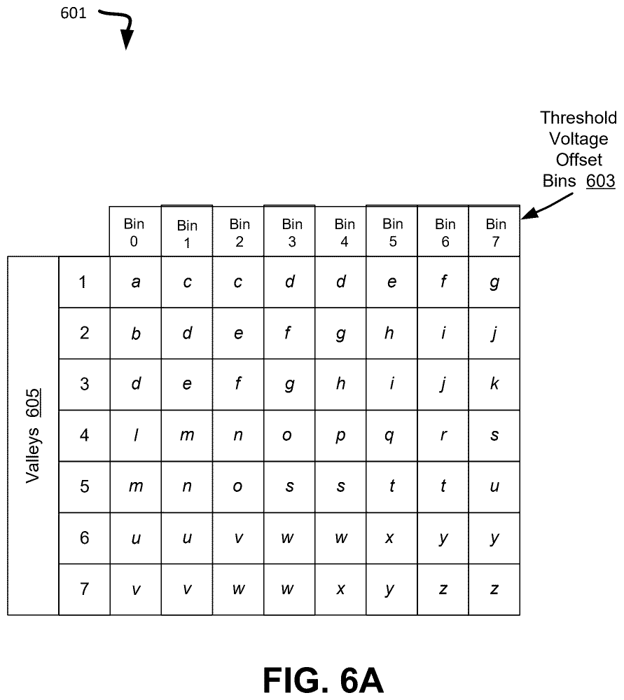

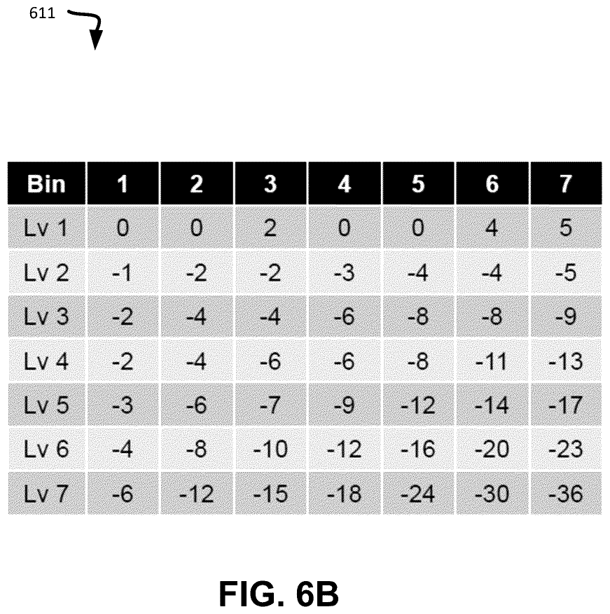

FIG. 6A is an example set of threshold voltage offset bins in accordance with some embodiments of the present disclosure. The first part calibration process determines a set of read level voltage offsets that result in a sub-optimal error rate not exceeding a maximum allowable error rate. FIG. 6A illustrates a data structure 601 with an example set of read level voltage offsets and the threshold voltage offset bins. This example set of read level voltage offsets is for a triple level cell (TLC), and thus has 7 valleys 605. Note that a set for a single-level cell (SLC) would have 1 valley, a set for a multi-level cell (MLC) would have 3 valleys, a set for a quad-level cell (QLC) would have 15 valleys, and so on. In the example illustrated in FIG. 6A, the set has 8 bins 603. The letters a-z represent read level voltage offsets. Note that letters a-z are an example; the read level voltage offsets can be the same in certain valleys and bins, or they can all be different. There can be more or fewer differing read level voltage offsets than illustrated in FIG. 6A (that is, the read level voltage offsets are not limited to the 26 a-z values illustrated in FIG. 6A). In one example, the memory sub-system controller may determine that read level voltage offset a, when applied to valley 1 of a TLC associated with bin-0, results in a suboptimal error rate not exceeding a maximum allowable error rate; read level voltage offset b, when applied to valley 2 of a TLC associated with bin-0, results in a suboptimal error rate not exceeding a maximum allowable error rate; read level voltage offset d, when applied to valley 3 of a TLC associated with bin-0, results in a suboptimal error rate not exceeding a maximum allowable error rate; and so on. FIG. 6B is a data structure 611 with a set of read level voltage offsets in example values.

In some embodiments, the processing device may determine a threshold voltage offset bin to be associated with a segment of the memory device. The segment of the memory device (e.g., cells, pages, blocks, planes, dies, etc.) can be grouped using different techniques described above to be associated with one of the threshold voltage offset bins. In one implementation, the segment of the memory device may be one or more of the families of blocks (or any other memory partitions) programmed within a specified time window and/or under similar environmental (e.g., temperature) conditions (e.g., BFEA technique or like).

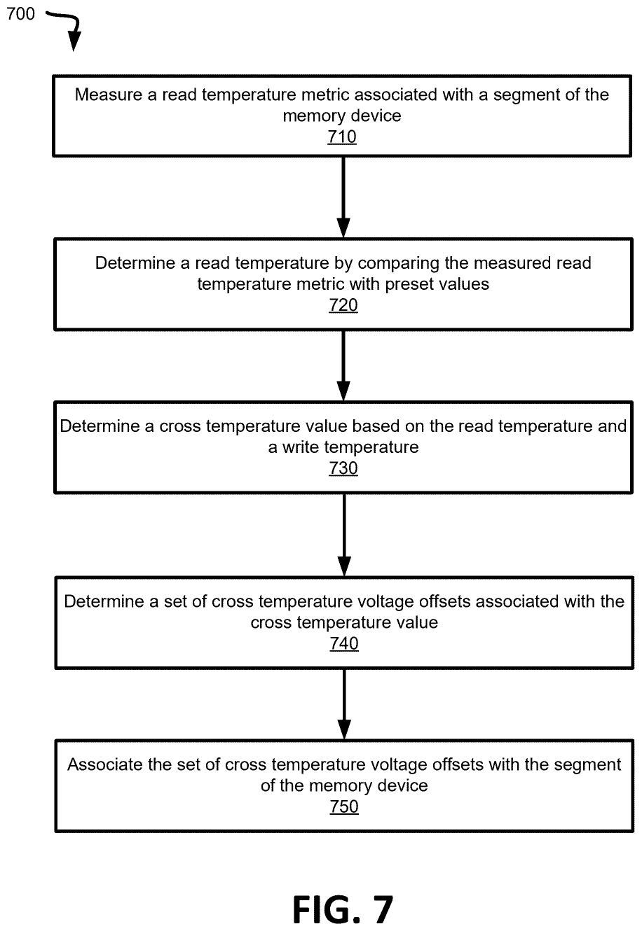

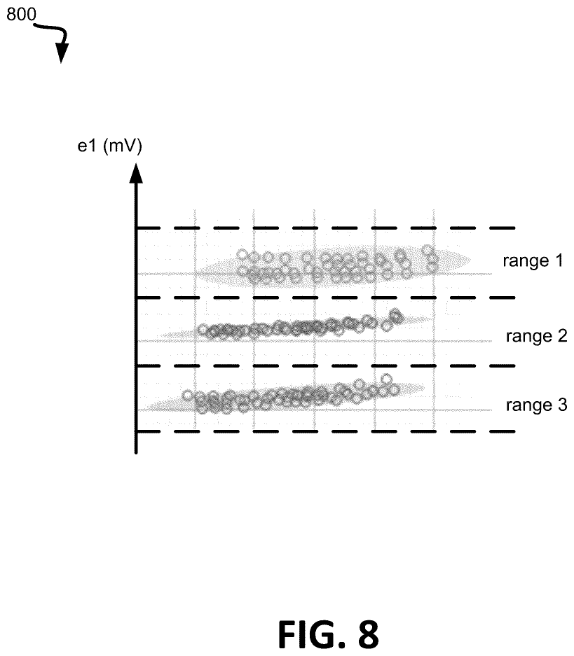

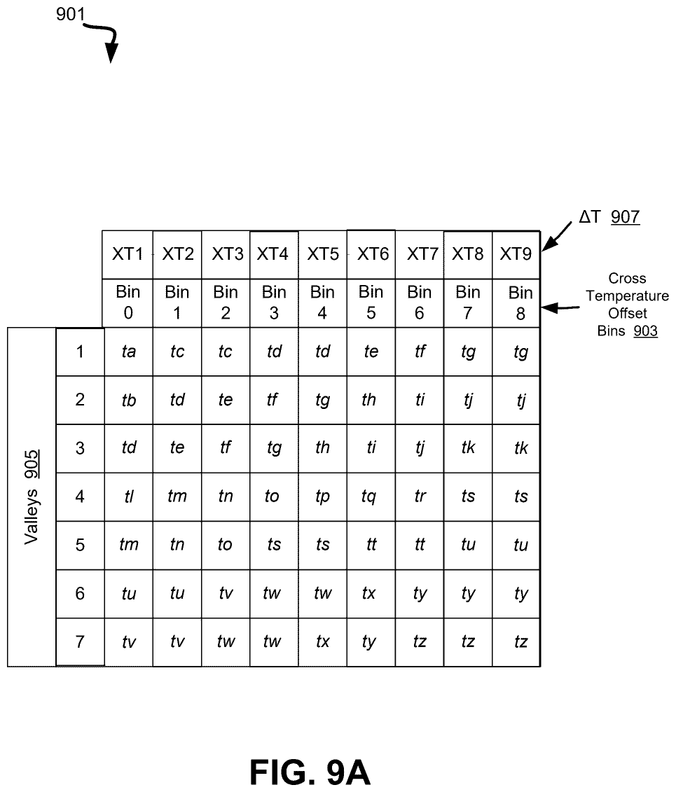

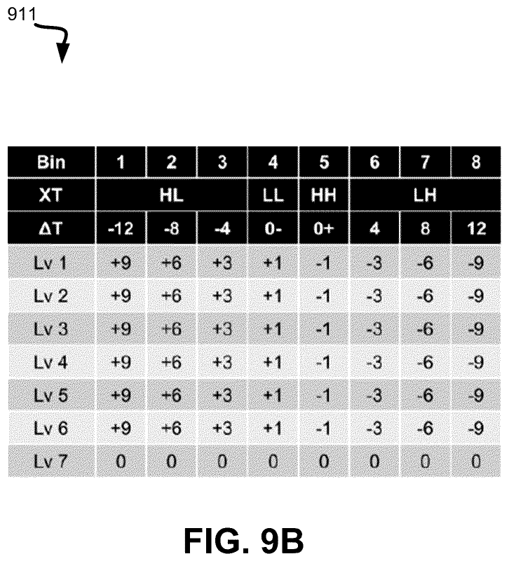

Referring back to FIG. 2, at operation 230, the processing device may perform the second part calibration associated with cross temperature offset bins due to write-read temperature variation. In some implantations, the processing device may perform a second part calibration in order to associate each die of each block family with one of the cross temperature offset bins. The second part calibration process can evaluate a read temperature for each die of each block family with one of a set of predefined threshold voltage offset bins, e.g., by, for each die of each block family, measuring a value of read temperature metric (e.g., a voltage shift) of a block (of the block family) stored on the die. An example of measuring a read temperature metric is illustrated later with respect to FIG. 5 and an example of determining the read temperature using the measured read temperature metric is illustrated later with respect to FIG. 8. The second part calibration process can retrieve, from a data store of the memory device, a write temperature for each die of each block family, where the write temperature is measured at the time of write operation and stored in the data store. The second part calibration process can then determine a cross temperature value by using the write temperature and the read temperature. The second part calibration process can then update another bin pointer (“cross temperature offset bin pointer”) associated with the die and block family to point to a cross temperature offset bin that corresponds to the cross temperature value. Each cross temperature offset bin is in turn associated with voltage offsets to be applied for read operations. An example set of cross temperature offset bins is illustrated with respect to FIG. 9A; for TLC with 8 distributions (levels) there are 7 valleys and for a given cross temperature offset bin, which includes 7 offsets, one for each valley. An example method 700 of performing the second part calibration associated with cross temperature offset bins due to write-read temperature variation is illustrated with respect to FIG. 7.

FIG. 7 is a flow diagram of an example method 700 to perform the second part calibration associated with cross temperature offset bins to further modify the read level voltage offsets, in accordance with some embodiments of the present disclosure. The method 700 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 700 is performed by the read voltage adjustment component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 710, the processing device may measure a read temperature metric associated with a segment of the memory device. In some implementations, the read temperature metric comprises a half valley margin of threshold voltage for a lowest state of each memory cell in the segment of the memory device. In some implementations, the processing device may measure a cross temperature metric for each die of each block family, e.g., by, for each die of each block family, measuring a value of cross temperature metric of a block (of the block family) stored on the die. An example of measuring a cross temperature metric is illustrated in FIG. 5. As shown in FIG. 5, the cross temperature metric may be calculated based on a value of a half valley margin of threshold voltage for a lowest state of a memory cell, for example, the cross temperature metric may equal e1. In some implementations, the processing device may periodically initialize a calibration process of a center of a voltage valley for a state of each memory cell in the segment of the memory device, where measuring the read temperature metric is performed responsive to initializing the calibration process.

At operation 720, the processing device may determine a read temperature by comparing the measured read temperature metric with preset values. In some implementations, the preset values defines a plurality of value ranges of the read temperature metric, and where each value range of the plurality of value ranges of the read temperature metric corresponds to a respective temperature of a plurality of temperatures, and wherein the read temperature is determined to be a temperature corresponding to a value range in which the measured read temperature metric falls in.

In some implementations, the processing device may determine the read temperature based on the measured read temperature metric according to a look-up data structure or a preset formula. The look-up data structure or a preset formula may reflect the relation between the read temperature metric and the read temperature and may be preset, for example, according to practical or testing data.

In some implementations, the set of cross temperature voltage offsets associated with the cross temperature value is determined by performing a look-up operation in cross temperature metadata (e.g., data structure 901 in FIG. 9A, data structure 911 in FIG. 9B) associated with the memory device, wherein the cross temperature metadata comprises a table including a plurality of records, wherein each record of the plurality of records associates s respective set of cross temperature voltage offsets with a respective cross temperature value and a respective cross temperature offset bin, and wherein associating the set of cross temperature voltage offsets with the segment of the memory device further involves associating a cross temperature offset bin with the segment of the memory device.

FIG. 8 illustrates an example of the relation between the read temperature metric and the read temperature. According to FIG. 8, the preset values of the read temperature metric (e.g., e1 measured in mV) may be divided into three ranges, for example, range 1 (e.g., covering x1 mV to y1 mV), range 2 (e.g., covering x2 mV to y2 mV), and range 3 (e.g., covering x3 mV to y3 mV), and each range corresponds to a temperature value (e.g., T1 for range 1, T2 for range 2, T3 for range 3). By comparing the measured read temperature metric with the ranges, the processing device may determine the measured read temperature falls in a range (e.g., range 1), and thus determine the read temperature corresponding to that range (e.g., T1). The number of ranges and the corresponding temperature illustrated in FIG. 8 are examples, and other format such as data structure or preset formular can also be used to represent the relation between the read temperature metric and the read temperature.

At operation 730, the processing device may determine a cross temperature value based on the read temperature and a write temperature of the segment of the memory device. In some embodiments, the write temperature of the segment of the memory device is obtained at the time of write operation, stored in a data store of the memory device, and retrieved from the data store; and the cross temperature value is determined as the read temperature reduced by the write temperature. In some embodiments, a temperature may be measured at the time of programming using a built-in temperature sensor (e.g., a small semiconductor diode that changes its electrical properties based on temperature), and the temperature may be assigned to the segment of the memory device as write temperature and stored in the data store for retrieving. In some embodiments, upon determining the read temperature, the processing device may retrieve a write temperature stored in the memory sub-system and subtract from the read temperature by the write temperature to obtain the cross temperature value.

In some embodiments, the processing device may determine the write temperature for a set of target cells, where the set of target cells may be defined to have the same write temperature. In one embodiment, memory sub-system controller 115 tracks the write temperature at a certain level of granularity, such as by segment, by memory die, by memory device, etc. Accordingly, the processing device (e.g., read voltage adjustment component 113) can retrieve the write temperature associated with the segment of the memory device including the target cells, such as from a data structure maintained in local memory 119 or elsewhere on memory device 130.

At operation 740, the processing device may determine a set of cross temperature voltage offsets associated with the cross temperature value. In some implementations, the processing device may determine the set of cross temperature voltage offsets associated with the cross temperature value by performing a look-up operation in cross temperature metadata (e.g., data structure 901 in FIG. 9A, data structure 911 in FIG. 9B) associated with the memory device. The cross temperature metadata can include a data structure, for example a table, which stores records, and each record in the table associates a cross temperature value (corresponding to a cross temperature offset bin) with a set of cross temperature voltage offsets. In one example, the cross temperature offset bin can be represented by the cross temperature metadata.

FIG. 9A is an example data structure including a set of cross temperature offset bins that can be used in the second part calibration process in accordance with some embodiments of the present disclosure. The second part calibration process determines a set of read level voltage offsets that result in a sub-optimal error rate not exceeding a maximum allowable error rate due to the temperature variation. FIG. 9A illustrates a data structure 901 with an example set of cross temperature voltage offsets, the cross temperature offset bins and the cross temperature values. This example set of read level voltage offsets is for a triple level cell (TLC), and thus has 7 valleys 605. Note that a set for a single-level cell (SLC) would have 1 valley, a set for a multi-level cell (MLC) would have 3 valleys, a set for a quad-level cell (QLC) would have 15 valleys, and so on. In the example illustrated in FIG. 9A, the set has 9 bins 903. The letters a-z represent read level voltage offsets. Note that letters a-z are an example; the read level voltage offsets can be the same in certain valleys and bins, or they can all be different. There can be more or fewer differing read level voltage offsets than illustrated in FIG. 9A (that is, the read level voltage offsets are not limited to the 26 a-z values illustrated in FIG. 9A). Each cross temperature offset bin 903 may correspond to a cross temperature value XT 907. In one example, XT1-XT3 may correspond to high-temperature write to low-temperature read; XT 4 may correspond to low-temperature write to low-temperature read; XT 5 may correspond to high-temperature write to high-temperature read; XT6-XT95 may correspond to low-temperature write to high-temperature read. In one example, the memory sub-system controller may determine that cross temperature voltage offset ta, when applied to valley 1 of a TLC associated with bin-0, based on XT1; read level voltage offset tb, when applied to valley 2 of a TLC associated with bin-0, based on XT1; read level voltage offset td, when applied to valley 3 of a TLC associated with bin-0, based on XT1; and so on. FIG. 9B is an example data structure 911 with a set of read level voltage offsets in example values.

At operation 750, the processing device may associate the set of cross temperature voltage offsets with the segment of the memory device. In some implementations, the processing device may associate a segment of memory device with a cross temperature offset bin during a periodically performed calibration process. The second part calibration process selects the set of voltage offsets to be applied to the base voltage read level in order to perform read operations with respect to a specified number of selected pages or blocks that is being calibrated.

In some implementations, the processing device may associate partitions of various families with one of the cross temperature offset bins. Each cross temperature offset bin, in turn, can be associated with a set of voltage offsets to be applied for read operations described with respect to operation 240. In some implementations, the processing device may associate a set of read level voltage offsets with the segment of the memory device, wherein the set of read level voltage offsets and the set of cross temperature voltage offsets are applied to a base read level threshold voltage associated with the segment of the memory device for a read operation. In some implementations, the processing device may create a block family associated with the segment of the memory device; and associating the block family with a threshold voltage offset bin; wherein the threshold voltage offset bin is associated with a set of read level voltage offsets by read level metadata (e.g., data structure 601 in FIG. 6A, data structure 611 in FIG. 6B) associated with the memory device, wherein the read level metadata comprises a table including a plurality of records, wherein each record of the plurality of records associates a respective set of read level voltage offsets with a respective threshold voltage offset bin, wherein associating the set of cross temperature voltage offsets with the segment of the memory device further comprises associating the set of cross temperature voltage offsets with the block family.

Referring back to FIG. 2, at operation 240, the processing device may store the associated threshold voltage offset bins (at operation 220) and the associated cross temperature bins (at operation 230) for use in the read operation or the read error handling operation. For example, when a read operation is requested, the processing device may identify, based on metadata associated with the memory device, the segment of the memory device associated with the physical address. The processing device may then utilize metadata to determine the threshold voltage offsets and the cross temperature voltage offsets. The processing device may compute a modified threshold voltage by applying the threshold voltage offset and the cross temperature voltage offsets to a base read level voltage associated with the memory device. The base read level voltage can be stored in the metadata area of the memory device. The processing device may utilize the modified threshold voltage in order to perform the requested read operation.

In some implementations, upon receiving a read command in the read operation or the read error handling operation, where the read command specifies an identifier of a logical block, the processing device can translate the identifier of the logical block into a physical address of a physical block stored on the segment of the memory device; identify a block family associated with the physical address; identify, based on metadata associated with the memory device, a set of threshold voltage offsets associated with the block family; identify, based on metadata associated with the memory device, the set of cross temperature voltage offsets associated with the segment of the memory device; compute a modified threshold voltage by applying the set of threshold voltage offsets and the set of cross temperature voltage offsets to a base read level voltage associated with the segment of the memory device die; and read, using the modified threshold voltage, data from the segment of the memory device.

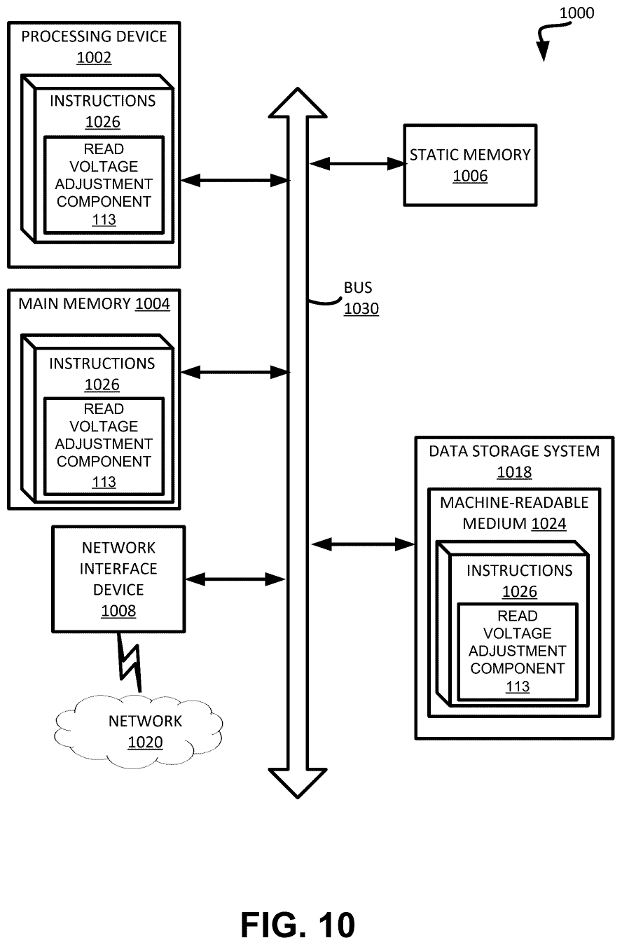

FIG. 10 illustrates an example machine of a computer system 1000 within which a set of instructions, for causing the machine to perform any one or more of the methodologies discussed herein, can be executed. In some embodiments, the computer system 1000 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the read voltage adjustment component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1000 includes a processing device 1002, a main memory 1004 (e.g., read-only memory (ROM), flash memory, dynamic random access memory (DRAM) such as synchronous DRAM (SDRAM) or RDRAM, etc.), a static memory 1006 (e.g., flash memory, static random access memory (SRAM), etc.), and a data storage system 1018, which communicate with each other via a bus 1030.

Processing device 1002 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1002 can also be one or more special-purpose processing devices such as an application specific integrated circuit (ASIC), a field programmable gate array (FPGA), a digital signal processor (DSP), network processor, or the like. The processing device 1002 is configured to execute instructions 1026 for performing the operations and steps discussed herein. The computer system 1000 can further include a network interface device 1008 to communicate over the network 1020.

The data storage system 1018 can include a machine-readable storage medium 1024 (also known as a computer-readable medium) on which is stored one or more sets of instructions 1026 or software embodying any one or more of the methodologies or functions described herein. The instructions 1026 can also reside, completely or at least partially, within the main memory 1004 and/or within the processing device 1002 during execution thereof by the computer system 1000, the main memory 1004 and the processing device 1002 also constituting machine-readable storage media. The machine-readable storage medium 1024, data storage system 1018, and/or main memory 1004 can correspond to the memory sub-system 110 of FIG. 1.

In one embodiment, the instructions 1026 include instructions to implement functionality corresponding to an offset bin update component (e.g., the read voltage adjustment component 113 of FIG. 1). While the machine-readable storage medium 1024 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled with the memory device, to perform operations comprising:
measuring a read temperature metric associated with a segment of the memory device;
estimating a read temperature based on the read temperature metric;
determining a cross temperature value based on the read temperature and a write temperature;
determining a set of cross temperature voltage offsets associated with the cross temperature value; and
associating the set of cross temperature voltage offsets with the segment of the memory device.

2. The system of claim 1, wherein the read temperature metric comprises a half valley margin of a threshold voltage for a lowest state of each memory cell in the segment of the memory device.

3. The system of claim 1, wherein estimating the read temperature based on the read temperature metric further comprises:
comparing the read temperature metric with a plurality of value ranges of the read temperature metric, wherein each value range of the plurality of value ranges of the read temperature metric corresponds to a respective temperature of a plurality of temperatures; and
determining the read temperature as a temperature corresponding to a value range in which the read temperature metric falls in.

4. The system of claim 1, wherein the set of cross temperature voltage offsets associated with the cross temperature value is determined by performing a look-up operation in cross temperature metadata structure associated with the memory device, wherein the cross temperature metadata structure comprises plurality of records, wherein each record of the plurality of records associates s respective set of cross temperature voltage offsets with a respective cross temperature value and a respective cross temperature offset bin, and
wherein associating the set of cross temperature voltage offsets with the segment of the memory device further comprises associating a cross temperature offset bin with the segment of the memory device.

5. The system of claim 1, wherein the operations further comprise:
associating a set of read level voltage offsets with the segment of the memory device, wherein the set of read level voltage offsets and the set of cross temperature voltage offsets are applied to a base read level threshold voltage associated with the segment of the memory device for a read operation.

6. The system of claim 1, wherein the operations further comprise:
creating a block family associated with the segment of the memory device; and
associating the block family with a threshold voltage offset bin; wherein the threshold voltage offset bin is associated with a set of read level voltage offsets by read level metadata associated with the memory device, wherein the read level metadata comprises a table including a plurality of records, wherein each record of the plurality of records associates a respective set of read level voltage offsets with a respective threshold voltage offset bin,
wherein associating the set of cross temperature voltage offsets with the segment of the memory device further comprises associating the set of cross temperature voltage offsets with the block family.

7. The system of claim 1, wherein the operations further comprise:
receiving a read command in a read operation or a read error handling operation, wherein the read command specifies an identifier of a logical block;
translating the identifier of the logical block into a physical address of a physical block stored on the segment of the memory device;
identifying a block family associated with the physical address;
identifying, based on metadata associated with the memory device, a set of threshold voltage offsets associated with the block family;
identifying, based on the metadata associated with the memory device, the set of cross temperature voltage offsets associated with the segment of the memory device;
computing a modified threshold voltage by applying the set of threshold voltage offsets and the set of cross temperature voltage offsets to a base read level voltage associated with the segment of the memory device die; and
reading, using the modified threshold voltage, data from the segment of the memory device.

8. A method comprising:
measuring, by a processing device, a read temperature metric associated with a segment of a memory device;
estimating a read temperature based on the read temperature metric;
determining a cross temperature value based on the read temperature and a write temperature;
determining a set of cross temperature voltage offsets associated with the cross temperature value; and
associating the set of cross temperature voltage offsets with the segment of the memory device.

9. The method of claim 8, wherein the read temperature metric comprises a half valley margin of a threshold voltage for a lowest state of each memory cell in the segment of the memory device.

10. The method of claim 8, wherein estimating the read temperature based on the read temperature metric further comprises:
comparing the read temperature metric with a plurality of value ranges of the read temperature metric, wherein each value range of the plurality of value ranges of the read temperature metric corresponds to a respective temperature of a plurality of temperatures; and
determining the read temperature as a temperature corresponding to a value range in which the read temperature metric falls in.

11. The method of claim 8, wherein the set of cross temperature voltage offsets associated with the cross temperature value is determined by performing a look-up operation in cross temperature metadata structure associated with the memory device, wherein the cross temperature metadata structure comprises plurality of records, wherein each record of the plurality of records associates s respective set of cross temperature voltage offsets with a respective cross temperature value and a respective cross temperature offset bin, and
wherein associating the set of cross temperature voltage offsets with the segment of the memory device further comprises associating a cross temperature offset bin with the segment of the memory device.

12. The method of claim 8, further comprising:
associating a set of read level voltage offsets with the segment of the memory device, wherein the set of read level voltage offsets and the set of cross temperature voltage offsets are applied to a base read level threshold voltage associated with the segment of the memory device for a read operation.

13. The method of claim 8, further comprising:
creating a block family associated with the segment of the memory device; and
associating the block family with a threshold voltage offset bin; wherein the threshold voltage offset bin is associated with a set of read level voltage offsets by read level metadata associated with the memory device, wherein the read level metadata comprises a table including a plurality of records, wherein each record of the plurality of records associates a respective set of read level voltage offsets with a respective threshold voltage offset bin,
wherein associating the set of cross temperature voltage offsets with the segment of the memory device further comprises associating the set of cross temperature voltage offsets with the block family.

14. The method of claim 8, further comprising:
receiving a read command in a read operation or a read error handling operation, wherein the read command specifies an identifier of a logical block;
translating the identifier of the logical block into a physical address of a physical block stored on the segment of the memory device;
identifying a block family associated with the physical address;
identifying, based on metadata associated with the memory device, a set of threshold voltage offsets associated with the block family;
identifying, based on the metadata associated with the memory device, the set of cross temperature voltage offsets associated with the segment of the memory device;
computing a modified threshold voltage by applying the set of threshold voltage offsets and the set of cross temperature voltage offsets to a base read level voltage associated with the segment of the memory device die; and
reading, using the modified threshold voltage, data from the segment of the memory device.

15. A non-transitory computer-readable storage medium comprising instructions that, when executed by a processing device, cause the processing device to perform operations comprising:
measuring a read temperature metric associated with a segment of a memory device;
estimating a read temperature based on the read temperature metric;
determining a cross temperature value based on the read temperature and a write temperature;
determining a set of cross temperature voltage offsets associated with the cross temperature value; and
associating the set of cross temperature voltage offsets with the segment of the memory device.

16. The non-transitory computer-readable storage medium of claim 15, wherein the read temperature metric comprises a half valley margin of a threshold voltage for a lowest state of each memory cell in the segment of the memory device.

17. The non-transitory computer-readable storage medium of claim 15, wherein estimating the read temperature based on the read temperature metric further comprises:
comparing the read temperature metric with a plurality of value ranges of the read temperature metric, wherein each value range of the plurality of value ranges of the read temperature metric corresponds to a respective temperature of a plurality of temperatures; and
determining the read temperature as a temperature corresponding to a value range in which the read temperature metric falls in.

18. The non-transitory computer-readable storage medium of claim 15, wherein the set of cross temperature voltage offsets associated with the cross temperature value is determined by performing a look-up operation in cross temperature metadata structure associated with the memory device, wherein the cross temperature metadata structure comprises plurality of records, wherein each record of the plurality of records associates s respective set of cross temperature voltage offsets with a respective cross temperature value and a respective cross temperature offset bin, and
wherein associating the set of cross temperature voltage offsets with the segment of the memory device further comprises associating a cross temperature offset bin with the segment of the memory device.

19. The non-transitory computer-readable storage medium of claim 15, wherein the operations further comprise:
associating a set of read level voltage offsets with the segment of the memory device, wherein the set of read level voltage offsets and the set of cross temperature voltage offsets are applied to a base read level threshold voltage associated with the segment of the memory device for a read operation.

20. The non-transitory computer-readable storage medium of claim 15, wherein the operations further comprise:
receiving a read command in a read operation or a read error handling operation, wherein the read command specifies an identifier of a logical block;
translating the identifier of the logical block into a physical address of a physical block stored on the segment of the memory device;
identifying a block family associated with the physical address;
identifying, based on metadata associated with the memory device, a set of threshold voltage offsets associated with the block family;
identifying, based on the metadata associated with the memory device, the set of cross temperature voltage offsets associated with the segment of the memory device;
computing a modified threshold voltage by applying the set of threshold voltage offsets and the set of cross temperature voltage offsets to a base read level voltage associated with the segment of the memory device die; and
reading, using the modified threshold voltage, data from the segment of the memory device.
